(19) United States
(12) Patent Application Publication
(10) Pub. No.: US 2012/0187754 A1
(43) Pub. Date: Jul. 26, 2012

(54) HYBRID ELECTRIC SHOVEL

(76) Inventor: Mark Emerson, Germantown, WI (US)

(21) Appl. No.: 13/014,228

(22) Filed: Jan. 26, 2011

(51) Int. Cl. B60L 1/00; H05K 13/00

(52) U.S. Cl. 307/9.1; 29/592.1

(57) ABSTRACT

A hybrid electric shovel. The hybrid electric shovel includes a main transformer, a first and second converter, a first and second DC motor, a first and second active front end, a first and second motion inverter, and a first and second AC motor. The first converter is coupled to a first secondary winding, and the second converter is coupled to a second secondary winding. The first DC motor is coupled to the first converter, and the second DC motor is coupled to the second converter. The first active front end is coupled to the first secondary winding and to the first motion inverter. The second active front end is coupled to the second secondary winding and to the second motion inverter. The first AC motor is coupled to the first motion inverter, and the second AC motor is coupled to the second motion inverter.

### BACKGROUND

The invention relates to an electric shovel, specifically a hybrid electric shovel using both direct current (DC) and alternating current (AC) motors.

Electric shovels are used for the extraction and dumping of earth and rock in mines. The shovels operate in one of two modes—digging and propelling. In the digging mode, a dipper is positioned next to the earth and rock (i.e., crowding). The dipper is then hoisted up through the earth, scooping up the earth. The shovel is then rotated (i.e., swinging) to position the dipper over a truck and the earth is deposited in the truck. Next, the shovel swings back, and the process is repeated.

FIG. 1 depicts an exemplary electric shovel 100 including a mobile base 105 supported on drive tracks 110. The mobile base 105 supports thereon a turntable 115, and a machinery deck 120. The turntable 115 permits full 360° rotation of the machinery deck 120 relative to the base 105.

A boom 125 is pivotally connected at 130 to the machinery deck 120. The boom 125 is held in an upwardly and outwardly extending relation to the deck by a brace or gantry in the form of tension cables 135 which are anchored to a back stay 140 of a stay structure 145 rigidly mounted on the machinery deck 120.

A dipper 150 is suspended by a flexible hoist rope or cable 155 from a pulley or sheave 160, the hoist rope is anchored to a winch drum 165 mounted on the machinery deck 120. As the winch drum rotates, the hoist rope 155 is either paid out or pulled in, lowering or raising the dipper 150. The boom pulley directs the tension in the hoist rope to pull straight upward on the shovel dipper thereby producing efficient dig force with which to excavate the bank of material. The dipper has an arm or handle 170 rigidly attached thereto, with the dipper arm 170 slideably supported in a saddle block 175, which is pivotally mounted on the boom 125 at 180. The dipper arm 170 has a rack tooth formation thereon (not shown) which engages a drive pinion or shipper shaft (not shown) mounted in the saddle block 175. The drive pinion is driven by an electric motor and transmission unit 185 to effect extension or retraction of the dipper arm 170 relative to the saddle block 175.

A source of electrical power is mounted on the machinery deck 120 to provide power to one or more hoist electric motors that drive the winch drum 165, a crowd electric motor that drives the saddle block transmission unit 185, and a swing electric motor which turns the machinery deck turntable 115. Each of the crowd, hoist, and swing motors is driven by its own motor controller, which responds to operator commands to generate the required voltages and currents.

The shovel boom 125 is a major structural component in size, shape, and weight. Its main purpose is to hold the boom pulley 160 in an advantageous position for efficient hoist dipper pull through the bank. Another major purpose of the boom 125 is to mount the shipper shaft at a sufficient height and outward radius from the centerline of rotation of the shovel 100. The shipper shaft powers the shovel handle to extend and retract the dipper 150. These two features of an electric shovel digging attachment make the shovel uniquely qualified to reach and dig high bank formations safely away from the shovel. The shovel in this regard is also able to reach a great volume of material in one sitting without propelling closer to the bank.

The different functions of the shovel (e.g., crowd, hoist, swing, and propel) are performed by one or more motors. FIG. 2 shows a schematic diagram of aspects of the prior art electric (DC) shovel 100. The shovel 100 receives AC electric power from a power source at a mine, for example, at a main disconnect switch 200. The main disconnect switch 200 couples power to a main transformer contactor 205, which couples the power to a primary winding 210 of a main transformer 215.

The main transformer 215 also includes a first secondary winding 220 and a second secondary winding 225. The first secondary winding 220 is coupled to a first switched capacitor bank 230, a first hoist full bridge thyristor converter 235, and a crowd full bridge thyristor converter 240. The second secondary winding 225 is coupled to a second switched capacitor bank 245, a second hoist full bridge thyristor converter 250, and a swing full bridge thyristor converter 255. Current transformers 260 measure the kVAR on each of the first and second secondaries 220 and 225, and the first and second switched capacitor banks 230 and 245 are controlled (e.g., switched) to provide reactive power compensation to maintain power factor and line voltage. The first and second switched capacitor banks 230 and 245 include large reactors to reduce inrush current and filter harmonics, and require periodic maintenance.

The first hoist full bridge thyristor converter 235 drives a first hoist motor 265. The crowd full bridge thyristor converter 240 is coupled to a crowd motor 270 through a contactor 275 and to a first propel motor 280 through a contactor 285. The second hoist full bridge thyristor converter 250 is coupled to a second hoist motor 290 through a contactor 295 and to a second propel motor 300 through a contactor 305. The swing full bridge thyristor converter 255 is coupled to a pair of swing motors 310 and 315 which are connected in series. In some constructions, three or more swing motors are used.

Each of the motors—the first and second hoist motors 365 and 290, the crowd motor 270, the first and second swing motors 310 and 315, and the first and second propel motors 280 and 300—are brushed DC motors. Each of the full bridge thyristor converters output 600 VDC.

The two hoist motors 265 and 290 are connected in a twelve-pulse series connection. In twelve-pulse series operation, DC-outputs of the converters 235 and 250 are connected in series with the motors 265 and 290. One converter acts as a master converter and is speed-controlled, while the other converter acts as a slave converter, which is controlled via firing angle. The configuration reduces harmonics, lowers reactive power content, and reduces torque ripple.

The thyristor firing and current control for the hoist motors is done using sequential firing. In twelve-pulse series operation, it is possible to operate in a sequential mode, with master and slave operating with different angles. Only one unit at a time is controlling, while the other is in a limit, corresponding to the minimum and the maximum firing angle. This results in reduced reactive power load for the mains. The current waveform ranges from pure six-pulse to pure twelve-pulse, and in between, with mixed waveforms and differing current peaks.

The propel motors 280 and 300 are located in the mobile base 105 of the shovel 100 (i.e., below the turntable 115 and near the tracks 110). Power is provided to the propel motors 280 and 300 through a slip-ring assembly. There are two rings for each motor (e.g., a plus connection and a minus connection) which carry the full armature current for each motor 280 and 300.

In dig mode, the shovel is able to hoist, crowd, and swing. In this mode all four converters are active (i.e., the first hoist converter 235, the second hoist converter 250, the crowd converter 240, and the swing converter 255), and the propel motors 280 and 300 are physically disconnected (via contactors 285 and 305).

In propel mode, the shovel is able to swing and propel. The outputs from the second hoist converter 250 and the crowd converter 240 are wired to an enclosure that contains contactors that switch between the second hoist motor 265 and the second propel motor 300, and the crowd motor 270 and the first propel motor 285, respectively.

Contactors are used because they are cheaper than two additional dedicated thyristor converters. In addition, the contactors take up less space than two dedicated thyristor converters, reducing space requirements on the machine.

In order to transfer from the dig mode to the propel mode, hoist and crowd brakes are set, and armature converters are turned off. The crowd converter 240 is then turned off, and hoist and crowd armature contactors (part of contactors 295 and 275) are opened. Next the crowd field contactor (part of the contactor 275) is opened. Propel armature contactors and field contactor (part of contactors 285 and 305) are closed next.

A propel field is then turned on. The crowd and second hoist converters 240 and 250 are turned on, and the propel brakes are released.

A reverse procedure is used to transfer from propel mode to dig mode.

The time required to transfer from one mode to the other takes from three to seven seconds in order to ensure safe sequencing. In situations where the shovel 100 is being propelled often, this can result in a significant loss of efficiency.

DC motors have a brush and a commutator that require maintenance to ensure the brushes are not too short, the brushes are wearing evenly, the commutator is filming nicely, and the commutator does not exhibit signs of sparking. In addition, DC motors operate within a commutation limit. DC motors can commutate more current at lower speeds than higher speeds. So to prevent sparking, armature current may be limited within the commutation limit at certain speeds.

DC digital drives have increased the capability and dynamics achieved with DC motor armature current and speed control. This increase in performance has increased the demand on shovel DC motors, and is evident in the hoist and crowd motions on shovels. Dynamic field weakening (to operate motors above base speed) and increased shovel payloads have pushed existing DC motor capabilities with great success.

Customer power supply capabilities are typically not ideal. Customers tend to operate the shovels with long trail cable lengths (far from the substation transformer supplying the shovel) and the power supply may have poor voltage regulation, which results in high transient voltages being developed. To combat the poor voltage regulation (a typical shovel shuts down when a drive under-voltage occurs), customers tap up the substation supply voltage in hopes of minimizing under-voltage warnings and faults.

The combination of weak power systems, long trailing cables (distributed capacitance), and elevated voltage levels have multiple effects: commutator stress, accelerated brush and commutator wear, arc horn damage, and increased hard machine shutdowns (drive under-voltage, hoist/crowd diverter trips). In addition, the transient voltages from the voltage supply are fed straight through the drive armature converters, directly affecting the motors.

The effects of elevated supply voltages have effects beyond drive and motor systems. With the higher voltage levels and transients, the operating voltages of other system components' are exceeded, such as capacitors of the switched capacitor banks 230 and 245, reducing their overall life.

High transient voltages can also have effects on the shovel main transformer 215, especially during energizing when high inrush currents are seen. These high peak voltages can, over time, affect transformer winding insulation, which can lead to a winding failure.

### SUMMARY

In one embodiment, the invention provides a hybrid electric shovel. The hybrid electric shovel includes a main transformer, a first and second converter, a first and second DC motor, a first and second active front end, a first and second motion inverter, and a first and second AC motor. The main transformer has a primary winding, a first secondary winding, and a second secondary windings. The first converter is coupled to the first secondary winding, and the second converter is coupled to the second secondary winding. The first DC motor is coupled to the first converter, and the second DC motor is coupled to the second converter. The first active front end is coupled to the first secondary winding and to the first motion inverter. The second active front end is coupled to the second secondary winding and to the second motion inverter. The first AC motor is coupled to the first motion inverter, and the second AC motor is coupled to the second motion inverter.

In another embodiment, the invention provides a method of modifying a DC electric shovel having a main transformer, a first switched capacitor bank, a second switched capacitor bank, a first hoist converter, a second hoist converter, a crowd converter, a swing converter, a first propel DC motor, a second propel DC motor, a first hoist DC motor, a second hoist DC motor, a first swing DC motor, a second swing DC motor, a crowd DC motor, and a plurality of contractors. The method includes removing at least two of the referenced DC motors, removing at least one of the referenced DC converters, removing the first and second switched capacitor banks, coupling an active front end to a secondary of the main transformer, coupling a motion inverter to the active front end, and coupling an AC motor to the motion inverter.

In another embodiment, the invention provides a method of modifying a direct current (DC) electric shovel having a main transformer, a first switched capacitor bank, a second switched capacitor bank, a first hoist converter, a second hoist converter, a crowd converter, a swing converter, a first propel DC motor, a second propel DC motor, a first hoist DC motor, a second hoist DC motor, a first swing DC motor, a second swing DC motor, a crowd DC motor, and a plurality of contactors. The method includes removing the first hoist DC motor, the second hoist DC motor, and the crowd DC motor, removing the first hoist converter, removing the first and second switched capacitor banks, removing the plurality of contactors, coupling a connection of the first propel DC motor that was connected to one of the plurality of contactors to the crowd converter, coupling a connection of the second propel DC motor that was connected to one of the plurality of contactors to the second hoist converter, coupling a first active front end to the first secondary, coupling a second active front end to the second secondary, coupling a first motion inverter to the first active front end, coupling a second motion inverter to the second active front end, coupling a first hoist AC motor to the first motion inverter, coupling a second hoist AC motor to the second motion inverter, and coupling a crowd AC motor to the second motion inverter. A connection of the first propel DC motor was connected to the crowd converter via one of the plurality of contactors, and a connection of the second propel DC motor was connected to the second hoist converter via another of the plurality of contactors.

Other aspects of the invention will become apparent by consideration of the detailed description and accompanying drawings.

### BRIEF DESCRIPTION OF THE DRAWINGS

FIG. 1 is a side view of an exemplary prior art electric shovel.

FIG. 2 is a schematic diagram for portions of a prior art DC electric shovel.

FIG. 3 is a schematic diagram for portions of a hybrid electric shovel.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways.

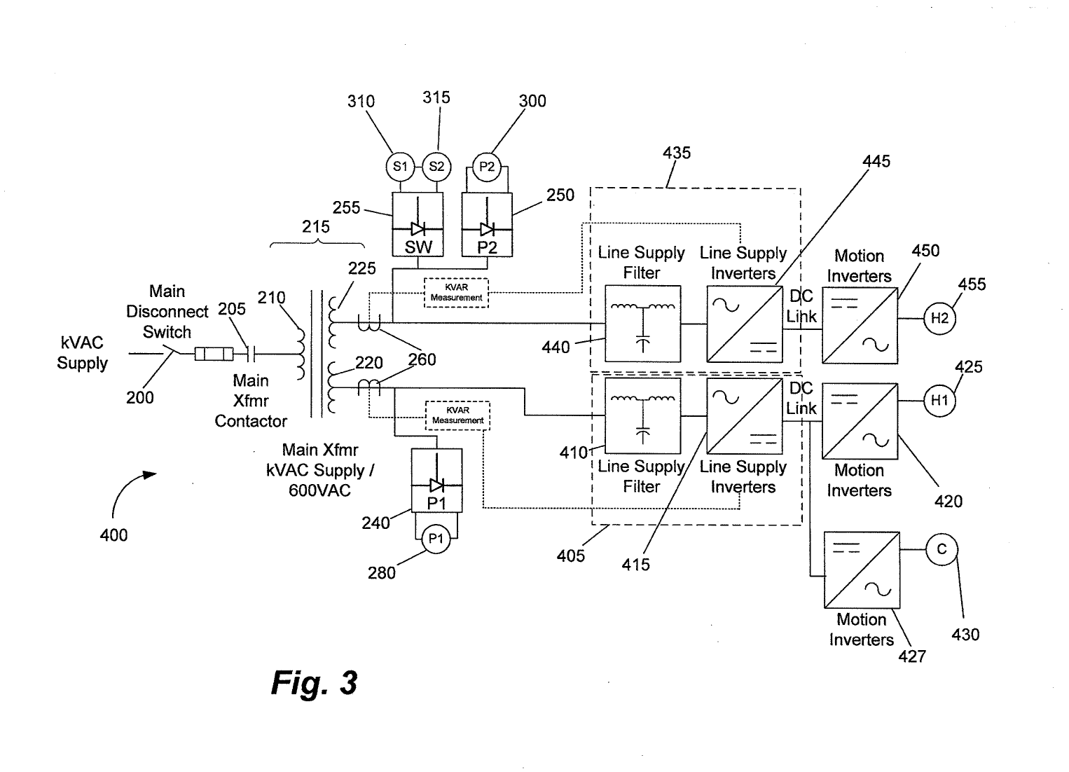

FIG. 3 shows a partial schematic of a hybrid electric shovel 400. The hybrid shovel 400 includes several components of the DC electric shovel 100 including the main disconnect switch 200, the main transformer contactor 205, the main transformer 215 (including the primary winding 210, the first secondary winding 220, and the second secondary winding 225) three full bridge thyristor converters (a first propel converter 240, a second propel converter 250, and a swing converter 255), first and second propel motors 280 and 300, and first and second swing motors 310 and 315. The propel motors 280 and 300 and the swing motors 310 and 315 are the same DC motors used in the DC electric shovel 100.

The second secondary winding 225 is coupled to the second propel full bridge thyristor converter 250, and the swing full bridge thyristor converter 255. The first secondary winding 220 is coupled to a first propel full bridge thyristor converter 240. Current transformers 260 measure the kVAR on each of the first and second secondaries 220 and 225. The swing full bridge thyristor converter 255 is coupled to the pair of swing motors 310 and 315, which are connected in series. In some constructions, three or more swing motors are used.

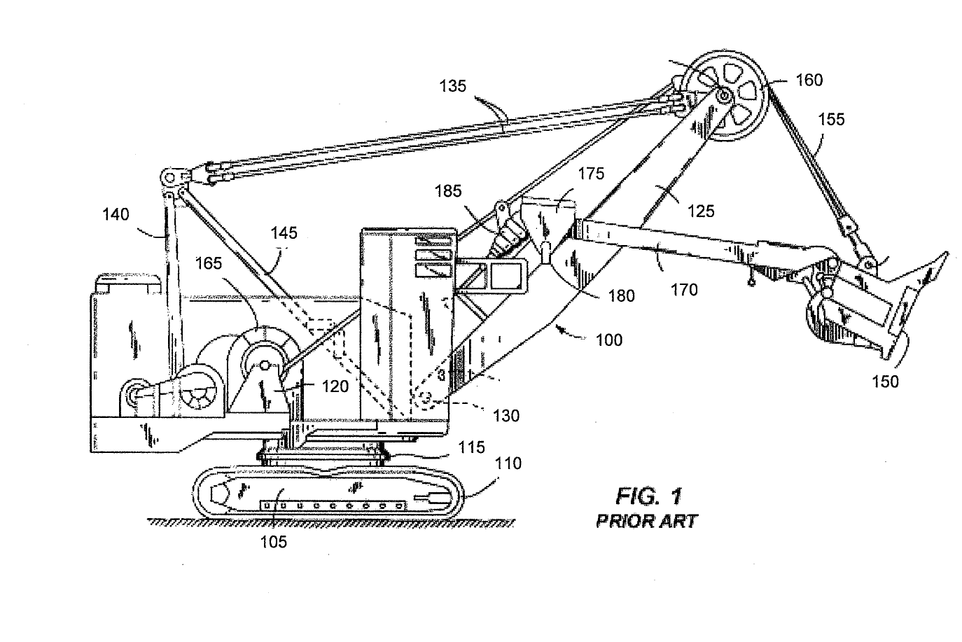

Before proceeding further, a DC shovel, such as the DC shovel 100 shown in FIG. 1, can be modified or “retrofit” with one or more AC motors to result in a hybrid shovel, such as the hybrid shovel 400 shown in FIG. 3. The modification of the DC shovel reduces maintenance and improves performance for the retrofit shovel 100, as will become clearer below.

The first secondary 220 is also connected to a first active front end 405, which includes a line supply filter 410 (e.g., an inductor-capacitor-inductor (LCL) filter) and a line supply inverter 415. The first active front end (AFE) 405 supplies reactive power compensation for the first propel converter 240 to maintain power factor, and also supplies power to a first inverter 420 that drives a first AC hoist motor 425 and a second inverter 427 that drives an AC crowd motor 430.

The second secondary 225 is also connected to a second active front end 435, which includes a line supply filter 440 (e.g., an LCL filter) and a line supply inverter 445. The second active front end (AFE) 435 supplies reactive power compensation for the swing converter 255 and the second propel converter 250 to maintain power factor, and also supplies power to a third inverter 450 that drives a first AC hoist motor 455.

In some constructions, the AFE's 405 and 435 (including the line supply filters 410 and 440 and the line supply inverters 415 and 445), and the motion inverts 420, 427, and 450 are designed using model ACS800 industrial drives, manufactured by ABB, Inc., New Berlin, Wis.

In some constructions, the AC hoist motors 425 and 455 are model HAF 8412 motors manufactured by P&H Mining Equipment, Milwaukee, Wis. In some constructions, the AC crowd motor 430 is a model HAF 7510 motor manufactured by P&H Mining Equipment, Milwaukee, Wis.

A control board (coupled to the current transformers 260) measures reactive power for each secondary 220 and 225. The control board controls the power electronics of the AFE's 405 and 435 to perform reactive power compensation and harmonic filtering for the active DC drives 240, 250, and 255.

The first propel full bridge thyristor converter 240 output and the second propel full bridge thyristor converter 250 output are wired directly to slip rings and the first and second propel motors 280 and 300, respectively.

In dig mode, the shovel is able to hoist, crowd, and swing. In this mode the swing full bridge thyristor converter 255 is active, and the first propel full bridge thyristor converter 240 and the second propel full bridge thyristor converter 250 are inactive.

The first AFE 405 (on the first secondary winding 220) delivers active power for the first and second motion inverters 420 and 427, and maintains unity power factor at the first secondary winding 220 terminals of the main transformer 215. The second AFE 435 (on the second secondary winding 225) compensates the swing converter 255 reactive power and delivers active power for the third motion inverter 450, while maintaining unity power factor at the second secondary winding 225 terminals of the main transformer 215.

In propel mode, the shovel is able to swing and propel. In this mode, all three converters 240, 250, and 255 are active, and none of the motion inverters 420, 427, and 450 are active.

The first AFE 405 on the first secondary winding 220 provides reactive power compensation for the first propel converter 240. The second AFE 435 on the second secondary winding 225 provides reactive power compensation for the swing and second propel converters 250 and 255.

To transfer from dig mode to propel mode, hoist and crowd brakes are set, and the inverters 420, 427, and 450 are turned off. The first propel and second propel converters 240 and 250 can then be immediately turned on. The propel field drive goes to full field, the propel brakes are released, and the shovel is ready for motion. The time required to set the brakes and activate the propel drives and motors is about 500-750 milliseconds, for example.

To transfer from propel mode to dig mode, the propel brakes are set, and the first and second propel converters 240 and 250 are turned off, causing the propel field drive to go to a minimum field current setting. Next the hoist and crowd drives 420, 427, and 450 are turned on, the brakes are released, and the shovel is ready for digging. Again, the time required to go to dig mode is about 500-750 milliseconds, for example.

AC motors do not have a brush and commutator, and require far less maintenance than an equivalent DC motor. In addition, AC motors have an absolute torque limit, known as breakdown torque. DC motors, have a separate field circuit and armature circuit, and can achieve very high torque output depending on the ability to supply current to the motor.

AC motors can operate at higher output speeds than DC motors because there is no commutator to limit current. The higher speeds at a given torque level allow for higher peak horsepower. As a result, AC drives can achieve just as high performance as a similar DC drive system.

Several power quality issues mentioned above are not as large a factor with the shovel 400. Long trail cable lengths and weak power systems do not affect the AFE's 405 and 435 as much as they affect DC systems (e.g., in shovel 100). Energy is stored in the DC link as well as the inductors in the line filters 410, and 440. This stored energy can be used to “ride through” periods of low supply voltages, allowing the AC system to handle conditions that the DC system cannot. A DC system has a hard under-voltage level (e.g., twenty percent below nominal voltage) that causes the shovel to trip. With the AC system, brief under-voltages of twenty-five percent or more below nominal voltage do not cause a machine shutdown.

In addition, transient voltages are reduced or eliminated due to active filtering done by the AFE's 405 and 435. As a result, the DC motors (i.e., the swing and propel motors 280, 300, 310, and 315) are not subjected to high transients.

Accordingly, because under-voltage shutdowns are drastically reduced, customers can supply the shovel with nominal voltage, and not have to tap up the supply voltage higher to minimize under-voltages, further reducing wear and tear on other components.

Instead of the fixed capacitor banks used in the DC system that are “stepped in” on both secondaries 220 and 225, the AFE's 405 and 435 are able to provide the required power compensation. In addition, the AFE's 405 and 435 and the AC inverters 420, 427, and 450 require much less maintenance than the switched capacitor banks and reactors.

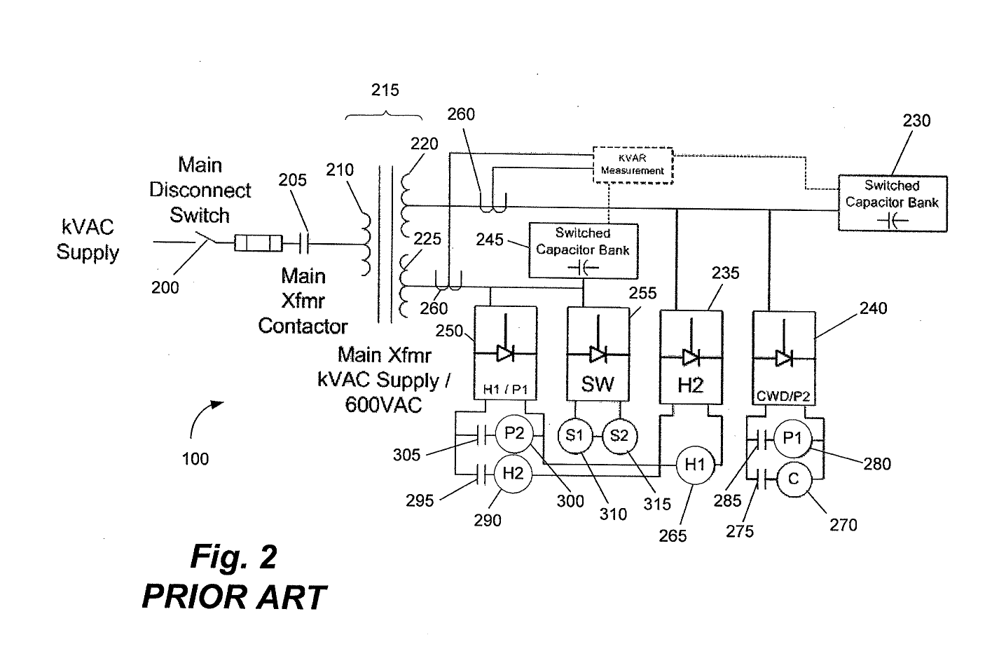

As stated previously, a prior art DC shovel, such as shovel 100, can be modified to become a hybrid shovel 400. Preventative maintenance of the prior art shovel 100 of FIG. 2 generally takes two to three weeks to complete. The invention provides for modifying the shovel 100 with AC motors (which require significantly less maintenance) during the normal preventative maintenance period of the shovel 100. Many shovels operating in the field are in use six thousand or more hours per year. Therefore, it is important to reduce downtime as much as possible.

During the modification, the propel and swing motors 280, 300, 310, and 315 receive their usual maintenance. The transfer contactor cabinet that allows the DC converter output to be switched from one motor to another is eliminated (i.e., the cabinet that controlled contactors 275, 285, 295, and 305). The contactors 275, 285, 295, and 305 require maintenance, thus their elimination results in reduced maintenance. The second hoist converter 235 is also eliminated, and parts can be saved for use as spare parts for the remaining converters 240, 250, and 255.

The switched capacitor banks 230 and 245 are completely removed. Reactive power compensation performed by the switched capacitor banks 230 and 245 is accomplished by the AFE's 405 and 435. The AFE's 405 and 435 create reactive power to compensate for the reactive power created by swing and propel converters 240, 250, and 255, and create active power to be delivered to the motion inverters 420, 427, and 450.

For this application, to take advantage of the higher speeds of the AC motors 425, 430, and 455, gearcase input pinions and sheaves are changed to give more gear ratio and to obtain equivalent torque outputs and horsepower as the DC motors 265, 270, and 290, with less motor torque. Thus, the hoist and crowd motors 425, 455, and 430 can achieve higher peak horsepower operation and higher top speeds compared to their equivalent DC motors 265, 270, and 290.

Improved reactive power compensation and power factor is achieved for the shovel 400 due to the capabilities and dynamic response of the AFE's 405 and 435. Power factor is maintained on each main transformer secondary 220 and 225, eliminating potential overloading of the secondaries (e.g., as can happen when the capacitor banks 230 and 245 are switched on and off for power factor correction).

By eliminating the sharing requirements of DC thyristor bridges for the crowd motor 270 and the first propel motor 280, and for the second hoist motor 290 and the second propel motor 300 (accomplished by the DC contactors 275, 285, 295, and 305), each propel motor 280 and 300 has its own dedicated DC thyristor converter 240 and 250. This removes the time delays associated with the thyristor bridge and contactor sequencing to enable the shovel 400 to propel substantially immediately upon request, increasing operational efficiency.

The existing main transformer 215 and overhead bus bars do not need to be changed for this modification, reducing installation time and costs. In addition, keeping the DC swing and propel motors 280, 300, 310, and 315 and slip ring assembly (two rings per motor for propel DC armature circuit, 4 rings total vs. 3 rings per motor for AC motor) reduces the installation time and costs as well as eliminating the need to change the slip ring assembly.

Common power electronic components (inverters) associated with the AC Line supply units 410, 415, 440, and 445 and motion inverters 420, 427, and 450 allow for faster time to troubleshoot/repair system failures, reduce component spare requirements, and advance system diagnostics vs. troubleshooting/repair time with the switched capacitor bank components such as large reactors and capacitors.

AC motors do not require the maintenance needed for DC motors with brushes and commutators. In addition, due to the highly dynamic nature of the load requirements for shovel hoist and crowd motions, as well as the possibility for a DC machine to flash or arc from brush holder to brush holder during certain operating conditions, maintenance intervals for DC motors are increased. The increased maintenance intervals for DC motors results in an even larger gap between the maintenance intervals for DC motors versus AC motors.

The invention has been described using the example of an electric shovel; however, the invention has application to other mining and construction machines that use DC motors.

Thus, the invention provides, among other things, a hybrid electric shovel and means to modify a DC electric shovel into the hybrid electric shovel. Various features and advantages of the invention are set forth in the following claims.

What is claimed is:

1. A method of modifying a direct current (DC) electric shovel having a main transformer, a first switched capacitor bank, a second switched capacitor bank, a first hoist converter, a second hoist converter, a crowd converter, a swing converter, a first propel DC motor, a second propel DC motor, a first hoist DC motor, a second hoist DC motor, a first swing DC motor, a second swing DC motor, a crowd DC motor, and a plurality of contactors, the method comprising:
removing at least two of the referenced DC motors;
removing at least one of the referenced DC converters;
removing the first and second switched capacitor banks;
coupling an active front end to a secondary winding of the main transformer;
coupling a motion inverter to the active front end; and
coupling an AC motor to the motion inverter.

2. The method of claim 1, wherein the removed DC motors include the first hoist motor, the second hoist motor, and the crowd motor.

3. The method of claim 1, wherein the removed DC converter is the first hoist converter.

4. The method of claim 1, further comprising removing the plurality of contactors, wherein a connection of the first propel DC motor was connected to the crowd converter via one of the plurality of contactors and a connection of the second propel DC motor was connected to the second hoist converter via another of the plurality of contactors.

5. The method of claim 4, further comprising coupling a connection of the first propel DC motor that was connected to one of the plurality of contactors to the crowd converter.

6. The method of claim 4, further comprising coupling a connection of the second propel DC motor that was connected to one of the plurality of contactors to the second hoist converter.

7. The method of claim 1, further comprising a second active front end coupled to a second secondary winding of the main transformer.

8. The method of claim 7, further comprising a second motion inverter coupled to the second active front end.

9. The method of claim 8, further comprising a second AC motor coupled to the second motion inverter.

10. The method of claim 9, further comprising a third AC motor coupled to the second motion inverter.

11. The method of claim 10, wherein the AC motor is a first hoist AC motor, the second AC motor is the second hoist AC motor, and the third AC motor is the crowd AC motor.

12. A hybrid electric shovel, the shovel comprising:
a main transformer having a primary winding, a first secondary winding, and a second secondary winding;
a first converter coupled to the first secondary winding;
a second converter coupled to the second secondary winding;
a first DC motor coupled to the first converter;
a second DC motor coupled to the second converter;
a first active front end coupled to the first secondary winding;
a second active front end coupled to the second secondary winding;
a first motion inverter coupled to the first active front end;
a second motion inverter coupled to the second active front end;
a first AC motor coupled to the first motion inverter; and
a second AC motor coupled to the second motion inverter.

13. The hybrid electric shovel of claim 12, further comprising a third converter coupled to the second secondary winding, and a third DC motor and a fourth DC motor coupled to the third converter.

14. The hybrid electric shovel of claim 13, wherein the first DC motor is a first propel DC motor, the second DC motor is a second propel DC motor, the third DC motor is a first swing DC motor, and the fourth DC motor is a second swing DC motor.

15. The hybrid electric shovel of claim 12, wherein the first active front end includes a line filter and a line supply inverter, and the second active front end includes a line filter and a line supply inverter.

16. The hybrid electric shovel of claim 12, further comprising a third AC motor coupled to the second motion inverter.

17. The hybrid electric shovel of claim 16, wherein the first AC motor is a first hoist AC motor, the second AC motor is a second hoist AC motor, and the third AC motor is a crowd AC motor.

18. A method of modifying a direct current (DC) electric shovel having a main transformer, a first switched capacitor bank, a second switched capacitor bank, a first hoist converter, a second hoist converter, a crowd converter, a swing converter, a first propel DC motor, a second propel DC motor, a first hoist DC motor, a second hoist DC motor, a first swing DC motor, a second swing DC motor, a crowd DC motor, and a plurality of contactors, the method comprising:
removing the first hoist DC motor, the second hoist DC motor, and the crowd DC motor;
removing the first hoist converter;
removing the first and second switched capacitor banks;
removing the plurality of contactors;
coupling a connection of the first propel DC motor that was connected to one of the plurality of contactors to the crowd converter;
coupling a connection of the second propel DC motor that was connected to one of the plurality of contactors to the second hoist converter;
coupling a first active front end to the first secondary;
coupling a second active front end to the second secondary;
coupling a first motion inverter to the first active front end;
coupling a second motion inverter to the second active front end;
coupling a first hoist AC motor to the first motion inverter;
coupling a second hoist AC motor to the second motion inverter; and
coupling a crowd AC motor to the second motion inverter;
wherein a connection of the first propel DC motor was connected to the crowd converter via one of the plurality of contactors, and a connection of the second propel DC motor was connected to the second hoist converter via another of the plurality of contactors.

19. The method of claim 18, further comprising coupling a connection of the first propel DC motor that was connected to one of the plurality of contactors to the crowd converter.

20. The method of claim 18, further comprising coupling a connection of the second propel DC motor that was connected to one of the plurality of contactors to the second hoist converter.
